(19) United States
(12) Patent Application Publication
(10) Pub. No.: US 2025/0237937 A1
(43) Pub. Date: Jul. 24, 2025

(54) LASER DEVICE AND PROJECTION SYSTEM

(71) Applicant: Hisense Laser Display Co., Ltd., Qingdao (CN)

(72) Inventors: Zinan Zhou, Qingdao (CN); Youliang Tian, Qingdao (CN); Yao Lu, Qingdao (CN); Zhaoshi Guo, Qingdao (CN)

(21) Appl. No.: 19/082,686

(22) Filed: Mar. 18, 2025

Related U.S. Application Data
(63) Continuation of application No. PCT/CN2023/119457, filed on Sep. 18, 2023.

(30) Foreign Application Priority Data
Oct. 13, 2022 (CN) 202222692471.6
Nov. 4, 2022 (CN) 202211377343.0

(51) Int. Cl. G03B 21/20

(52) U.S. Cl. CPC G03B 21/2033; G03B 21/2013; G03B 21/2066; G03B 21/208

(57) ABSTRACT

A laser device, comprising a housing, a plurality of laser chip assemblies and a reshaping component. The housing comprises: a bottom plate; and a sidewall connected to the bottom plate. The plurality of laser chip assemblies is arranged on the bottom plate. The reshaping component is connected to the sidewall. The reshaping component defines a first enclosed space together with the housing. The plurality of laser chip assemblies is disposed within the first enclosed space, and the reshaping component is disposed in a light-output path of at least a portion of the laser chip assemblies.

This application is a continuation of PCT Application No. PCT/CN2023/119457, filed Sep. 18, 2023, which claims priority to Chinese patent application No. 202211377343.0 filed Nov. 4, 2022 and Chinese patent application No. 202222692471.6 filed Oct. 13, 2022, all of which are incorporated herein by reference in their entireties for all purposes.

### TECHNICAL FIELD

The present disclosure relates to the field of display technologies, and particularly relates to a laser device and a projection system.

### BACKGROUND

With the development of laser projection technology, projection devices have gradually appeared in people's daily lives and become common articles for people's work and lives. A light source in a projection device can emit laser light of various colors, which are used to form projection pictures. Moreover, the higher the symmetry of the laser light of various colors emitted by the light source, the better the mixing effect and the better the display effect of the projection pictures.

### SUMMARY

In an aspect, a laser device is provided. The laser device includes a housing, a plurality of laser chip assemblies, and a reshaping component. The housing includes a bottom plate and a sidewall, and the bottom plate is connected to the sidewall. The plurality of laser chip assemblies are arranged on the bottom plate, and the reshaping component is connected to the sidewall. The reshaping component and the housing together define a first enclosed space, and the plurality of laser chip assemblies are disposed within the first enclosed space. The reshaping component is disposed in a light-emitting path of at least a portion of the laser chip assemblies.

In another aspect, a projection system is provided. The projection system includes at least one laser device as described in the above aspect, an optical modulation component disposed on a light-output side of the laser device, and a projection lens disposed on a light-output side of the optical modulation component.

### BRIEF DESCRIPTION OF DRAWINGS

For a clearer description of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a curve graph showing intensity distribution of laser beams according to some embodiments;

FIG. 2 is a sectional view of a laser device according to some embodiments;

FIG. 3 is a three-dimensional diagram of a housing according to some embodiments;

FIG. 4 is a sectional view of another laser device according to some embodiments;

FIG. 5 is a structural diagram of a diffractive optical element according to some embodiments;

FIG. 6 is a curve graph showing diffraction efficiency of laser light according to some embodiments;

FIG. 7 is a structural diagram of a planar reflecting mirror according to some embodiments;

FIG. 8 is a sectional view of another laser device according to some embodiments;

FIG. 9 is a sectional view of another laser device according to some embodiments;

FIG. 10 is a sectional view of another laser device according to some embodiments;

FIG. 11 is a sectional view of another laser device according to some embodiments;

FIG. 12 is a sectional view of another laser device according to some embodiments;

FIG. 13 is a sectional view of another laser device according to some embodiments;

FIG. 14 is a sectional view of another laser device according to some embodiments;

FIG. 15 is a structural diagram of a projection system according to some embodiments;

FIG. 16 is a structural diagram of another projection system according to some embodiments;

FIG. 17 is a three-dimensional diagram of another laser device according to some embodiments;

FIG. 18 is a sectional view of another laser device according to some embodiments;

FIG. 19 is a top view of a laser chip assembly of another laser device according to some embodiments;

FIG. 20 is a front view of a laser chip assembly of another laser device according to some embodiments;

FIG. 21 is a side view of another laser chip assembly of another laser device according to some embodiments;

FIG. 22 is a schematic diagram showing diffraction orders of a reflective diffraction grating according to some embodiments;

FIG. 23 is graph showing a wavelength distribution of a laser chip assembly of another laser device after wavelength tuning according to some embodiments; and

FIG. 24 is a sectional view of another laser device according to some embodiments.

### DETAILED DESCRIPTION

The technical solutions in some embodiments of the present disclosure will be clearly and completely described below in conjunction with the accompanying drawings. It is clear that the described embodiments are only a part of the embodiments of the present disclosure, and not all of the embodiments. Based on the embodiments provided in the present disclosure, all other embodiments obtained by a person of ordinary skill in the art fall within the scope of protection of the present disclosure.

Unless required otherwise in the context, throughout the specification and the claims, the term “comprise” and other forms thereof, such as the singular form in the third personal “comprises” and the present participle form “comprising”, are interpreted to have an open and inclusive meaning, i.e. “including, but not limited to”. In the description of the specification, the terms such as “one embodiment”, “some embodiments”, “exemplary embodiments”, “an example”, “a specific example” and “some examples” are intended to indicate that a particular feature, structure, material, or characteristic associated with the embodiment or example is included in at least one embodiment or example of the present disclosure. Illustrative expressions of the above terms do not necessarily refer to the same embodiment or example. Moreover, the particular feature, structure, material, or characteristic described may be included in any one or more embodiments or examples in any appropriate manner.

Hereinafter, the terms “first” and “second” are used for descriptive purposes only and are not to be understood as indicating or implying relative importance or implicitly specifying the number of technical features indicated. Thus, a feature defined with the term “first” or “second” may expressly or implicitly include one or more such features. In the description of the embodiments of the present disclosure, unless otherwise specified, “a plurality of” means two or more.

In the description of some embodiments, the expression “connect” and its derivatives may be used. The term “connect” is to be understood in a broad sense, for example, the “connection” may be a fixed connection, a detachable connection, or an integral connection, and may be a direct connection or an indirect connection through an intermediate medium.

“At least one of A, B and C” has the same meaning as “at least one of A, B or C”, including the following combinations of A, B and C: A only, B only, C only, a combination of A and B, a combination of A and C, a combination of B and C, and a combination of A, B and C.

As used herein, the term “if” is optionally interpreted, depending on the context, to mean “when . . . ”, “in response to determining”, or “in response to detecting”. Similarly, the phrase “if it is determined that . . . ” or “if [a stated condition or event] is detected” is optionally interpreted, depending on the context, to mean “upon determining . . . ”, “in response to determining . . . ”, “upon detecting [the stated condition or event]”, or “in response to detecting [the stated condition or event]”.

The use of “used for” or “configured to” herein implies open and inclusive language that does not exclude devices that are used for or configured to execute additional tasks or steps.

Additionally, the use of “based on” implies openness and inclusiveness because a process, step, calculation, or other action that is “based on” one or more of the stated conditions or values may be based on additional conditions or values beyond those stated in practice.

As used herein, “about”, “roughly”, or “approximately” includes a stated value and an average value that falls within an acceptable range of deviation from a particular value. The acceptable range of deviation is determined by one of ordinary skill in the art taking into account the measurement being discussed and errors associated with the measurement of a particular quantity (i.e., limitations of the measurement system).

As used herein, the use of “parallel”, “perpendicular”, and “equal” includes the situations described and situations similar to the situations described. The range of the similar situations is within an acceptable range of deviation, and the acceptable range of deviation is as determined by one of ordinary skill in the art taking into account the measurement being discussion and errors associated with the measurement of a particular quantity (i.e., limitations of the measurement system). For example, the term “parallel” includes absolutely parallel and approximately parallel, and an acceptable range of deviation for being approximately parallel may be, for example, within a deviation of 5°. The term “equal” includes absolutely equal and approximately equal, and the acceptable range of deviation for being approximately equal may be, for example, that the difference between the two that are equal is less than or equal to 5% of one of the two.

Example embodiments are described herein with reference to sectional and/or plane views that serve as idealized example accompanying drawings. In the accompanying drawings, the thicknesses of the layers and regions are enlarged for clarity. Therefore, there may be variations in shape relative to the accompanying drawings caused by, for example, manufacturing techniques and/or tolerances. Thus, example embodiments should not be construed as being limited to the shapes of the regions illustrated herein, but rather include shape deviations caused by, for example, manufacturing. For example, an etched region shown as rectangular generally has curves. Accordingly, the regions shown in the accompanying drawings are essentially schematic and their shapes are not intended to illustrate the actual shapes of the regions of the device and are also not intended to limit the scope of the example embodiments.

A projection display is to magnify an image and display the image on a projection screen using an optical system and projection space by controlling a light source based on flat image information. With the development of projection display technology, the projection display is gradually applied to business activities, conferences and exhibitions, science education, military command, traffic management, centralized monitoring and advertising and entertainment, etc., and the advantages of the larger display screen size, display clarity, etc. are also suitable for the requirements of large-screen display.

Currently, the commonly used projection systems have a digital light processing (DLP) architecture, with a digital micromirror device (DMD) as the core device. A light source emits light, which is then incident on the DMD to generate images, then the emergent light of the image generated by the DMD is incident on a projection lens, and images are generated by the projection lens and finally received by a projection screen.

A Multi-Chip LD (MCL) laser device is generally used as the projection light source, and the MCL laser device has a high degree of integration, which is beneficial for the miniaturization of the laser light source. The MCL laser device is generally integrated with a number of laser chips, and some MCL laser devices may include light laser chips of three basic colors of light (i.e., three kinds of laser chips, with each kind of laser chip emitting one base color of light). Therefore, the MCL laser device can emit three base colors of light.

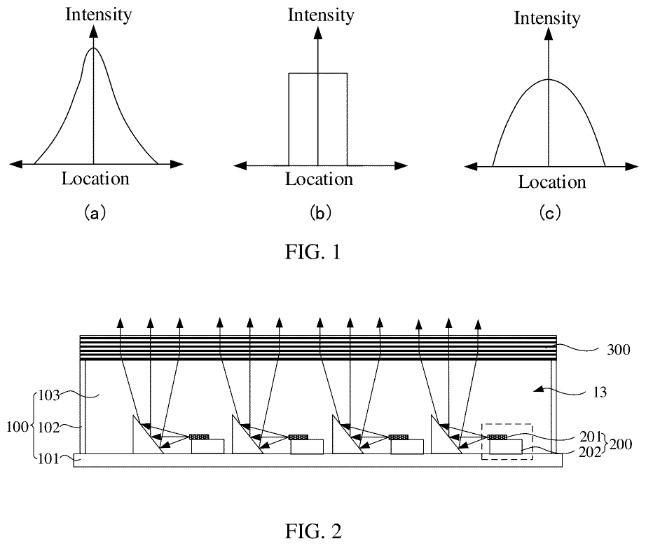

FIG. 1 is a curve graph showing intensity distribution of laser beams according to some embodiments.

As shown in (a) of FIG. 1, the energy of light beams emitted from the laser chips in the MCL laser device is in a Gaussian distribution, with a larger light intensity at a center position and a sharp decrease in the light intensity at edge positions. Laser chips that emitting light beams having energy in this distribution cannot meet the requirements of uniform illumination.

In order to achieve uniform illumination, laser light emitted from the MCL laser device needs to be converted into flat-topped beams. As shown in (b) of FIG. 1, the flat-topped beams have a uniform light intensity at various positions, which meets the illumination requirements in the projection system.

In some embodiments, a diffusion sheet is provided on the light-output side of the MCL laser device to homogenize the light beams emitted from the MCL laser device, thereby homogenizing the light intensity of the laser beams. However, the diffusion sheet cannot achieve a satisfactory effect of homogenizing light beams, and the energy distribution of the light beams has a higher brightness in the center and a lower brightness at the edges, with the intensity of the light beams changing from (a) of FIG. 1 to (c) of FIG. 1.

In some embodiments, the diffusion angle of the laser beams emitted from the MCL laser device is increased, such that the light intensities of the laser beams are distributed more uniformly, however, a significant amount of edge energy is lost.

In addition, it is necessary to provide a light pipe, a fly-eye lens, or other homogenizing parts on the light-output side of the projection light source in a projection system to homogenize light. However, a large amount of energy is lost when the light emitted from the laser light source is irradiated into a narrow light pipe. In order to achieve a certain degree of uniformity, it is necessary to extend the light pipe to more than 30 mm, but this will increase the length of the optical engine and is not beneficial for the miniaturization of the projection system.

Based on the above, some embodiments of the present disclosure provide a projection system 10, including a laser device 1. The laser device 1 can effectively homogenize the intensity distribution of laser beams, so there is no need to additionally provide a light pipe in the projection system 10, which is beneficial for the small size design of the projection system 10.

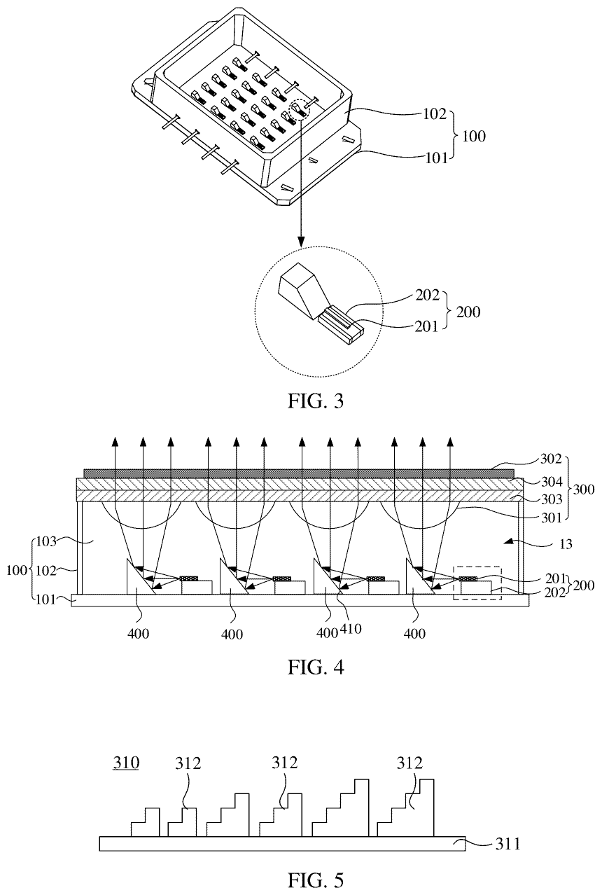

FIG. 2 is a sectional view of a laser device according to some embodiments, and FIG. 3 is a three-dimensional diagram of a housing according to some embodiments.

In some embodiments, as shown in FIG. 2 and FIG. 3, the laser device includes a housing 100, a plurality of laser chip assemblies 200, and a reshaping component 300.

The housing 100 is configured to accommodate the laser chip assemblies 200 so as to package the laser chip assemblies 200. The housing 100 includes a bottom plate 101 and a sidewall 102. The sidewall 102 is annular in shape. The sidewall 102 is arranged on the bottom plate 101 and is substantially perpendicular to the bottom plate 101. The bottom plate 101 and the sidewall 102 together define an accommodation cavity 13.

In some embodiments, the bottom plate 101 and the sidewall 102 are made of the same material. For example, the bottom plate 101 and the sidewall 102 are made of oxygen-free copper, kovar metal or the like, that is, the bottom plate 101 and the sidewall 102 are oxygen-free copper material pieces or kovar metal material pieces.

The plurality of laser chip assemblies 200 are fixedly arranged on the bottom plate 101 and are disposed in the accommodation cavity 13.

In some embodiments, the laser chip assembly 200 includes a laser chip 201 and a heat sink 202. The heat sink 202 is arranged on the bottom plate 101, and the laser chip 201 is arranged on the heat sink 202. The heat sink 202 is configured to dissipate heat from the laser chip 201, and the laser chip 201 is configured to emit laser beams.

In some embodiments, the laser chip 201 and the heat sink 202 are soldered together using a high-precision eutectic soldering machine to form a laser chip assembly, which is also referred to as a chip on submount (COS) component.

In some embodiments, the heat sink 202 is a metal material piece. It will be appreciated that the heat sink 202 may also be made of other materials with good thermal conductivity, which is not limited in the present disclosure.

The reshaping component 300 is connected to the sidewall 102 and is disposed on the side of the sidewall 102 facing away from the bottom plate 101. The side of the sidewall 102 facing away from the bottom plate 101 is open to form an opening. The shape of the reshaping component 300 matches the shape of the opening, and the reshaping component 300 is connected to the housing 100 using adhesive glue, by soldering, etc., and the reshaping component 300 blocks off the opening. Therefore, the reshaping component 300 defines a first enclosed space 103 together with the housing 100. Furthermore, the laser chip assemblies 200 are arranged within the first enclosed space 103, such that the laser chip assemblies 200 can be well protected.

In some embodiments, the reshaping component 300 is disposed in the light-output paths of the laser chip assemblies 200 and is configured to receive the laser beams emitted from the laser chip assemblies 200 and to collimate and diffractively homogenize the received laser beams. In this way, the laser beams emitted from the laser chip assemblies 200, which are in a Gaussian distribution with a higher intensity in the center and a lower intensity at the edges, can be shaped by the reshaping component 300 into a flat-topped beam with a uniform intensity distribution.

It is to be understood that the flat-topped beams with uniform intensity distribution as the projection light source meets the illumination requirements in the projection system 10, so there is no need to provide components such as light pipes, fly-eye lenses, diffusion sheets in the projection system 10, which can reduce the energy loss caused by excessive components and is beneficial for the simplification of the structural design of the projection system 10.

In addition, the reshaping component 300 can replace the sealing glass of the projection system in the related art, and the reshaping component 300 and the housing form the first enclosed space 103 to seal the laser chip assemblies, thereby achieving the integration of the functions of the optical components inside the laser device 1, which is beneficial for the miniaturized design of the laser device 1 and the projection system 10.

In the following, the structure of the reshaping component 300 will be described in detail.

FIG. 4 is a sectional view of another laser device according to some embodiments.

In some embodiments, as shown in FIG. 4, the reshaping component 300 includes a plurality of first collimating portions 301 and a diffracting portion 302.

The plurality of first collimating portions 301 are disposed on the side of the reshaping component 300 close to the laser chip assemblies 200. Each first collimating portion 301 of the plurality of first collimating portions 301 is arranged in correspondence to one laser chip assembly 200. The first collimating portion 301 is configured to receive the laser beam emitted from the corresponding laser chip assembly 200 and to collimate the received laser beam.

The diffracting portion 302 is disposed on the side of the first collimating portions 301 facing away from the laser chip assemblies 200. The laser beam collimated by the first collimating portion 301 is incident on the diffracting portion 302. The diffracting portion 302 is configured to diffractively homogenize the received collimated laser beams such that the energy of the laser beams is uniformly distributed, that is, shape the laser beams which are in a Gaussian distribution into flat-topped beams with a uniform energy distribution, thereby satisfying the illumination requirements of the projection system 10.

FIG. 5 is a structural diagram of a diffractive optical element according to some embodiments.

In some embodiments, as shown in FIG. 5, the diffracting portion 302 includes a diffractive optical element (DOE) 310, and the diffractive optical element 310 includes a substrate 311 and a plurality of diffractive structures 312 disposed on the substrate 311, with the diffractive structures 312 being distributed in a two-dimensional matrix. The diffractive structures 312 are configured to make laser beams that pass through the diffractive structures 312 diffract and interfere with each other at a particular distance, thereby forming a particular light intensity distribution.

In some embodiments, the diffractive structures 312 distributed in two dimensions are formed by etching through a micro-nano etching process, and each diffractive structure 312 has a specific morphology, size, refractive index, and the like, so as to finely tune the wavefront phase distribution of laser light.

For example, the morphology, size, refractive index, and the like of each diffractive structure 312 are designed according to parameters such as the wavelength of an incident laser beam, the beam aperture, the beam pattern, the near-field intensity distribution, etc., and the microstructural morphology features are obtained by computer simulation, thereby achieving homogenized regulation.

It is to be understood that, as shown in FIG. 1, by specially designing each diffractive structure 312 of the diffracting portion 302, the laser beams shown in (a) of FIG. 1 with Gaussian distribution, after passing through the diffracting portion 302, can be homogenized into flat-topped beams with a uniform energy distribution shown in (b) of FIG. 1, thereby satisfying the illumination requirements of the projection system 10.

In some embodiments, under the shaping effect of the diffracting portion 302 on the laser beams, the laser beams incident on the diffracting portion 302 can be converted into rectangular light spots with a shape and size that match the shape and size of the DMD in the projection system 10. It is to be understood that the rectangular light spots are irradiated onto the DMD for projection display, so there is no need to additionally provide a shaping component specifically used for adjusting the shape of the light spot in the projection system 10, which is beneficial for the simplification of the structure of the projection system 10.

In some embodiments, the diffractive structures 312 of the diffracting portion 302 are designed as a plurality of individual structures, for example, stepped structures as shown in FIG. 5. In some embodiments, the diffracting portion 302 includes a plurality of diffractive structure 312 of different shapes, for example, the diffractive structures 312 include microstructures having a diffraction homogenization function, such as a serrated structure, a trapezoidal structure, a tilted rectangular structure, or a stepped structure. It is to be noted that the structure of the diffractive structure 312 is set according to actual needs, which is not limited in the present disclosure.

In some embodiments, the diffraction efficiency of the diffractive optical element 310 satisfies formula (1):

$${η}^{m} ( λ , θ ) = sin {c}^{2} ( m - \frac{φ ( λ , θ )}{2 π} ) ; \qquad ( 1 )$$

In formula (1), η represents a diffraction efficiency; λ represents a wavelength of laser light; θ represents an incident angle of the laser light incident on a diffractive optical element; m represents a diffraction order; c represents light speed in a vacuum; and φ(λ, θ) represents a function related to the wavelength λ and the incident angle θ of the laser light, whose form is related to the structure of the diffractive optical element. The diffraction efficiency η is a decreasing function of the incident angle θ.

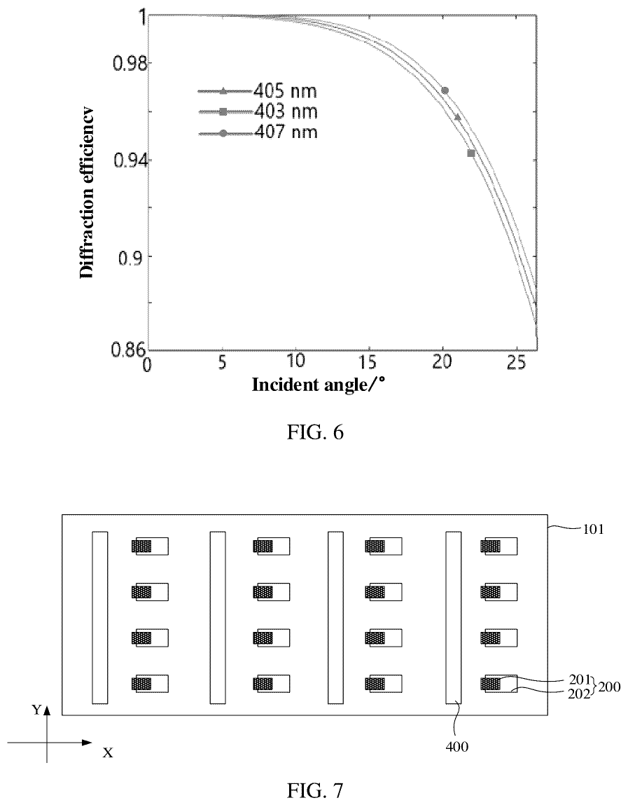

FIG. 6 is a curve graph showing diffraction efficiency of laser light according to some embodiments.

In some embodiments, as shown in FIG. 6, the horizontal coordinate in FIG. 6 represents the incident angle θ at which the laser light is incident on the diffractive optical element 310, and the vertical coordinate represents the diffraction efficiency of the incident laser light. For example, laser beams with wavelengths of 403 nm, 405 nm, and 407 nm respectively are incident on the diffractive optical element 310, and diffraction efficiency curves are obtained for the laser beams after passing through the diffractive optical element 310, respectively.

As can be seen from FIG. 6, the laser beams of three different wavelengths are incident on the diffraction optical element 310 in sequence from a smaller incident angle to a larger incident angle, and the diffraction efficiency of the laser beams of the three different wavelengths decreases with the increase of the incident angle. Therefore, in order to improve the diffraction efficiency of the laser light passing through the diffractive optical element 310 and to improve the illumination of the projection light source, it is necessary to ensure that the laser beams are incident on the diffractive optical element 310 at a smaller incident angle.

It is to be understood that, in some embodiments of the present disclosure, a plurality of first collimating portions 301 are provided on the incident side of the diffracting portion 302, and the plurality of first collimating portions 301 collimate a plurality of laser beams incident on the plurality of first collimating portions 301 so as to reduce the divergence angle of the plurality of laser beams and reduce the difference in the incident angles of the plurality of laser beams. In this way, the plurality of laser beams that are collimated can be incident on the diffracting portion 302 in a relatively parallel propagation direction, thereby simplifying the design difficulty of the diffracting portion 302 and improving the diffraction efficiency of the diffracting portion 302.

In some embodiments, as shown in FIG. 4, the laser device further includes a plurality of planar reflecting mirrors 400.

The plurality of planar reflecting mirrors 400 are disposed within the housing 100, and any one of the plurality of planar reflecting mirrors 400 corresponds to the at least one laser chip assembly 200 and is arranged on the light-output side of the corresponding at least one laser chip assembly 200. The planar reflecting mirror 400 has a flat first reflective surface 410, and the first reflective surface 410 faces the light-output side of the corresponding at least one laser chip assembly 200 and is configured to receive at least one laser beam emitted from the corresponding at least one laser chip assembly 200 and reflect the at least one laser beam received to the first collimating portion 301.

For example, the planar reflecting mirror 400 is arranged on the bottom plate 101 of the housing 100, and the first reflective surface 410 is arranged to face the corresponding at least one laser chip assembly 200, which is not limited in the present disclosure.

FIG. 7 is a structural diagram of a planar reflecting mirror according to some embodiments.

In some embodiments, as shown in FIG. 7, the plurality of planar reflecting mirrors 400 are arranged along a first direction X, and any one of the plurality of planar reflecting mirrors 400 extends along a second direction Y. The plurality of laser chip assemblies 200 are arranged in a plurality of columns along the first direction X and are arranged in a plurality of rows along the second direction Y. That is, the plurality of laser chip assemblies 200 are arranged in an array. In this way, one planar reflecting mirror 400 corresponds to a plurality of laser chip assemblies 200 and can reflect the laser beams emitted from the plurality of laser chip assemblies 200, thereby reducing the difficulty of manufacturing and installing the planar reflecting mirrors 400.

In some embodiments, the plurality of planar reflecting mirrors 400 may also be arranged in correspondence to the plurality of laser chip assemblies 200, that is, each of the planar reflecting mirrors 400 is configured to reflect the laser beam emitted from one corresponding laser chip assembly 200, which is not limited in the present disclosure.

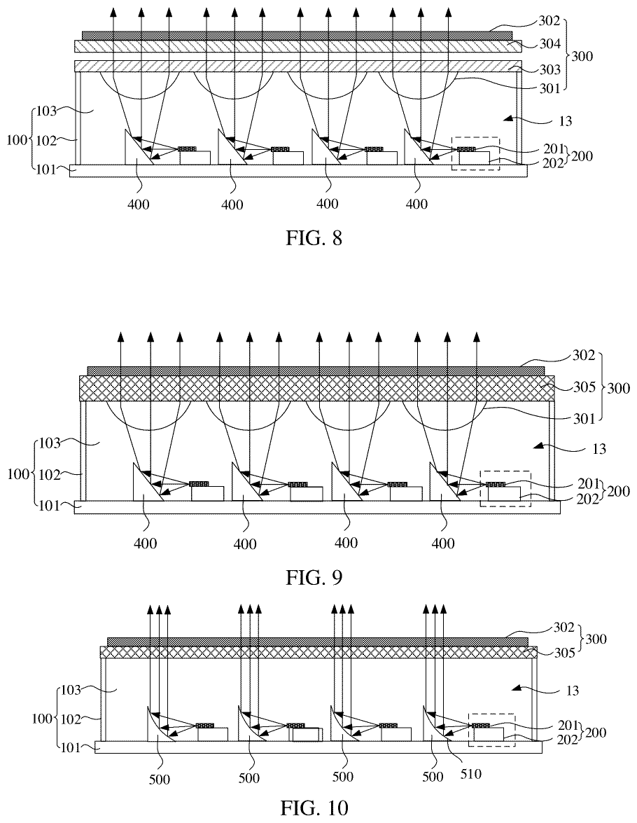

FIG. 8 is a sectional view of another laser device according to some embodiments.

In some embodiments, as shown in FIG. 4 and FIG. 8, the reshaping component 300 further includes a first substrate 303 and a second substrate 304. The first substrate 303 is disposed on the side of the sidewall 102 facing away from the bottom plate 101, and defines the first enclosed space 103 together with the housing 100, and the second substrate 304 is disposed on the side of the first substrate 303 facing away from the housing 100.

It should be noted that the first substrate 303 and the second substrate 304 may be made of the same or different materials, which is not limited in the present disclosure.

In some embodiments, the plurality of first collimating portions 301 are arranged on a side surface of the first substrate 303, and the diffracting portion 302 is arranged on a side surface of the second substrate 304. The side surface of the first substrate 303 on which no first collimating portions 301 are not arranged is attached to the side surface of the second substrate 304 on which no diffracting portion 302 is arranged, such that the first collimating portions 301 is disposed on the side of the first substrate 303 facing the laser chip assemblies 200, and the diffracting portion 302 is disposed on the side of the second substrate 304 facing away from the first substrate 303, thereby forming the reshaping component 300 as shown in FIG. 4.

In some embodiments, the reshaping component 300 includes a plurality of first collimating portions 301 and at least one diffracting portion 302. The plurality of first collimating portions 301 are arranged on a side surface of the first substrate 303, and the at least one diffracting portion 302 is arranged on at least one side surface of the second substrate 304. The first substrate 303 and the second substrate 304 are spaced apart from each other by a set distance (e.g., the set distance is greater than the thickness of the diffracting portion 302) in a direction perpendicular to the bottom plate 101. The first collimating portions 301 are disposed on the side of the first substrate 303 facing the laser chip assemblies 200, and the at least one diffracting portion 302 is disposed on the side of the second substrate 304 facing away from the first substrate 303, on the side of the second substrate 304 facing the first substrate 303, or on both sides of the second substrate 304, thereby forming the reshaping component 300 as shown in FIG. 8.

It is to be understood that it is convenient to adjust the setting method of the diffracting portion 302 by spacing apart the first substrate 303 and the second substrate 304 by a set distance, thereby enriching the use scenarios of the reshaping component 300.

In some embodiments, as shown in FIG. 4 and FIG. 8, the first substrate 303 is in contact with the sidewall 102 to form the first enclosed space 103, and the second substrate 304 is disposed on the side of the first substrate 303 facing away from the bottom plate 101.

In some embodiments, the second substrate 304 may also be arranged to be in contact with the sidewall 102 to form the first enclosed space 103, and the first substrate 303 is disposed within the first enclosed space 103 and is on the side of the second substrate 304 facing the bottom plate 101, which is not limited in the present disclosure.

FIG. 9 is a sectional view of another laser device according to some embodiments.

In some embodiments, as shown in FIG. 9, the reshaping component 300 further includes a substrate 305. The substrate 305 is disposed on the side of the sidewall 102 facing away from the bottom plate 101, and defines the first enclosed space 103 together with the housing 100. The plurality of first collimating portions 301 are disposed on the surface of the side of the substrate 305 facing the laser chip assemblies 200, and the diffracting portion 302 is disposed on the surface of the side of the substrate 305 facing away from the first collimating portions 301.

The diffracting portion 302, the substrate 305, and the plurality of first collimating portions 301 together form an integral structure having a collimating function and a diffraction homogenization function. In this way, the laser light emitted from the laser chip assemblies 200 is first collimated by the first collimating portions 301, and then is incident on the diffracting portion 302 and is diffracted and homogenized by the diffracting portion 302. Therefore, the diffraction efficiency of the diffracting portion 302 can be improved.

It is to be understood that the internal structure of the laser device 1 can be simplified by manufacturing the reshaping component 300 as an integral structure, which helps to reduce the size of the laser device 1 and the projection system 10, improve the assembly efficiency of the laser device 1, and reduce the assembly difficulty.

In some embodiments, the integral structure of the substrate 305 and the plurality of first collimating portions 301 is manufactured by an injection molding process, and then the plurality of diffractive structures 312 are manufactured on the surface of side of the substrate 305 facing away from the first collimating portions 301 by a micro-nano etching process, thereby forming the integral structure having the collimating function and the diffraction homogenizing function.

In some embodiments, the plurality of first collimating portions 301 are a plurality of protruding convex lenses or Fresnel lenses formed on the surface of the substrate 305. Each first collimating portion 301 is disposed in the light-output path of a corresponding laser chip assembly 200 and is configured to collimate the laser beam emitted from the corresponding laser chip assembly 200.

It should be noted that since the laser beams emitted from the laser chip assemblies 200 have different wavelengths and divergence angles, the parameters (e.g., focal length or refractive index, etc.) of each of the first collimating portions 301 need to be designed according to the collimation requirements on the light emitted from the corresponding laser chip assembly 200.

In some embodiments, the first collimating portion 301 may also be in other structures, which is not limited in the present disclosure.

FIG. 10 is a sectional view of another laser device according to some embodiments.

In some embodiments, as shown in FIG. 10, the laser device 1 includes a housing 100, a plurality of laser chip assemblies 200, a reshaping component 300, and a plurality of curved reflecting mirrors 500. The curved reflecting mirrors 500 are arranged within the housing 100, and each of the plurality of curved reflecting mirrors 500 is arranged in correspondence to one laser chip assembly 200 and is disposed on the light-output side of the corresponding laser chip assembly 200. The curved reflecting mirror 500 has a second reflective surface 510, which is a concave curved surface, and the second reflective surface 510 is configured to receive the laser beams emitted from the corresponding laser chip assembly 200, collimate the received laser beams, and reflect the collimated laser beams to the diffracting portion 302 in the reshaping component 300.

In some embodiments, the curved reflecting mirror 500 is arranged on the bottom plate 101 of the housing 100, and the second reflective surface 510 is arranged to face the corresponding laser chip assembly 200, which is not limited in the present disclosure.

It is to be understood that the second reflective surface 510 of the curved reflecting mirror 500 is designed as a curved surface, such that the curved reflecting mirror 500, upon receiving the divergent beams emitted from the laser chip assembly 200, can shrink the beams and adjust them into parallel collimated beams, and then reflect the collimated beams to the diffracting portion 302. In this way, the plurality of curved reflecting mirrors 500 can not only replace the plurality of the first collimating portions 301 to collimate the laser beams, but also can replace the plurality of planar reflecting mirrors 400 to reflect the collimated beams to the diffracting portion 302. Thereby, the first collimating portions 301 and the planar reflecting mirrors 400 can be simplified into a single component, and the structure of the laser device 1 can be further simplified.

In some embodiments, the shape of the second reflective surface 510 of the curved reflecting mirror 500 is designed specifically according to the collimation requirements on the laser chip assembly 200, such that the curved reflecting mirror 500 can shrink and collimate the laser light in fast-axis direction, shrink and collimate the laser light in the slow-axis direction, or shrink and collimate the laser light in both the fast-axis direction and the slow-axis direction, which is not limited herein.

In some embodiments, the substrate 305 is disposed on the side of the sidewall 102 facing away from the bottom plate 101, and the substrate 305 defines the first enclosed space 103 together with the housing 100. The diffracting portion 302 is disposed on the surface of the side of the substrate 305 facing away from the curved reflecting mirror 500, or the diffracting portion 302 is disposed on the surface of the side of the substrate 305 facing the curved reflecting mirror 500.

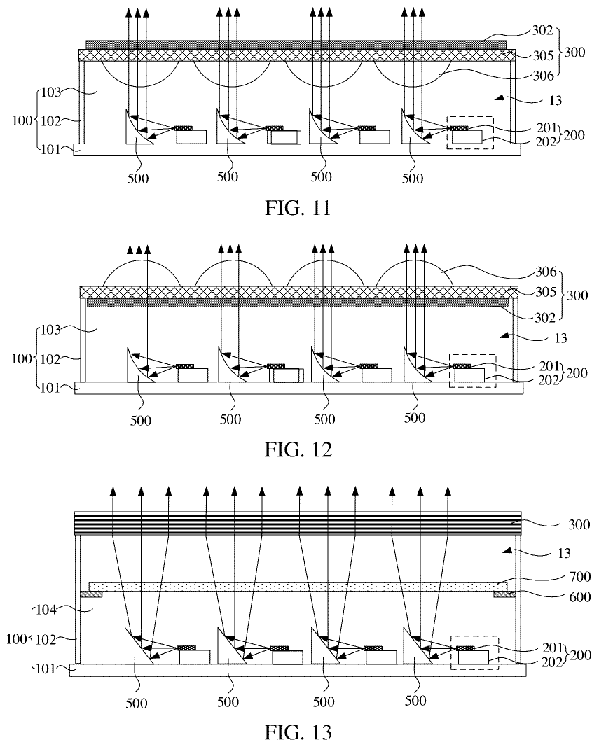

FIG. 11 is a sectional view of another laser device according to some embodiments, and FIG. 12 is a sectional view of another laser device according to some embodiments.

In some embodiments, as shown in FIG. 11 and FIG. 12, the reshaping component 300 further includes a plurality of second collimating portions 306. The plurality of second collimating portions 306 are arranged on the substrate 305 and are configured to further collimate the collimated laser beams from the curved reflecting mirrors 500.

It is to be understood that due to the limitation of the manufacturing process, the collimation degree of the collimated laser beams cannot meet the usage requirements in the case that the laser beams are collimated only by the collimating portions (e.g., the first collimating portions 301 or the second collimating portions 306) or the curved reflecting mirrors 500. Therefore, by providing the curved reflecting mirrors 500 and the second collimating portions 306 in the laser device 1, the laser beams can be collimated twice, such that the collimated laser beams can meet the usage requirements.

In some embodiments, the diffracting portion 302 is arranged on the surface of the side of the substrate 305 facing away from the curved reflecting mirrors 500, and the second collimating portions 306 are arranged on the surface of the side of the substrate 305 facing the curved reflecting mirrors 500. In this way, the laser beams emitted from the laser chip assemblies 200, after being collimated twice by the curved reflecting mirrors 500 and the second collimating portions 306, can be incident on the diffracting portion 302 at a higher collimation degree, which helps to improve the diffraction efficiency of the diffracting portion 302.

In some embodiments, the diffracting portion 302 may also be arranged on the surface of the side of the substrate 305 facing the curved reflecting mirrors 500, and the second collimating portions 306 may be arranged on the surface of the side of the substrate 305 facing away from the curved reflecting mirrors 500.

In some embodiments, the second collimating portions 306 are convex lenses or Fresnel lenses, which is not limited in the present disclosure.

FIG. 13 is a sectional view of another laser device according to some embodiments.

In some embodiments, the laser device 1 further includes a support portion 600 and sealing glass 700. In the following, the structure of the laser device 1 will be illustrated using the laser device 1 shown in FIG. 13 as an example.

As shown in FIG. 13, the support portion 600 is arranged on an inner wall of the sidewall 102 and extends circumferentially along the sidewall 102. The sealing glass 700 is arranged on the support portion 600 and seals the support portion 600. The bottom plate 101, a portion of the sidewall 102, the support portion 600 and the sealing glass 700 together define a second enclosed space 104.

In some embodiments, the support portion 600 and the sidewall 102 are an integral structure.

In some embodiments, the support portion 600 is fixed to the inner wall of the sidewall 102 by a soldering process such as eutectic soldering.

In some embodiments, the support portion 600 may also be fixed to the inner wall of the sidewall 102 in other manners, which is not limited herein.

In some embodiments, the sealing glass 700 is connected and fixed to the support portion 600 by a soldering process such as eutectic soldering, so as to ensure that the gas tightness of the second enclosed space 104 meets the design requirements of the laser device 1.

It is to be understood that the laser chip 201 generates a large amount of heat during the light emitting process, causing the temperature of the air around the laser chip 201 to rise, and the high temperature air reacts with water and oxygen in air, which easily affects the laser chip 201 and reduces the service life of the laser chip 201. Therefore, the laser chip 201 is packaged in an enclosed environment with a lower water-oxygen concentration (e.g., the second enclosed space 104), such that the laser chip 201 can be protected.

In some embodiments, the reshaping component 300 is fixedly connected to the housing 100 by a soldering process such as eutectic soldering.

In some embodiments, the reshaping component 300 may also be fixedly connected to the housing 100 using adhesive glue.

It is to be understood that during the installation of the laser device 1, the reshaping component 300 needs to be frequently moved in position such that the diffracting portion 302 and the first collimating portion 301 (or the second collimating portion 306) can collimate and homogenize the laser beams emitted from the corresponding laser chip assembly 200, which is beneficial for improving the optical performance of the laser device 1. In this case, if the reshaping component 300 is fixedly connected to the housing 100 by a soldering process, it is necessary to pre-coat the soldering position with metal coating for soldering. When the reshaping component 300 is moved in position greatly, the actual soldering position may not correspond to the preset soldering position, resulting in soldering failure, which affects the sealing performance and structural stability of the laser device 1.

Therefore, compared with the sealing method, it is simple and easy to operate to fixedly connect the reshaping component 300 to the housing 100 using adhesive glue.

In some embodiments, the substrate 305 (or the first substrate 303 and the second substrate 304) are connected to the housing 100 using the adhesive glue in a vacuum environment or an inert gas environment, such that the water-oxygen concentration within the first enclosed space 103 can be reduced, thereby protecting the laser chips.

However, as the laser chip 201 generates a large amount of heat during the light emitting process, the high temperature air causes the adhesive glue to evaporate and diffuse into the first enclosed space 103, and the adhesive glue reacts with the laser chip 201. As a result, the service life of the laser chip 201 is reduced.

In this case, the support portion 600 and the sealing glass 700 are arranged within the first enclosed space 103, and the sealing glass 700 is fixed to the support portion 600 by eutectic soldering or the like in a vacuum environment or an inert gas environment, so that the sealing glass 700, the support portion 600 and the housing 100 together define the second enclosed space 104. It is to be understood that the water-oxygen concentration is lower in the second enclosed space 104, and the second enclosed space 104 is blocked from the adhesive glue by the sealing glass 700 and the support portion 600, thereby preventing the adhesive glue from volatilizing due to the high temperature air, which helps to prolong the service life of the laser chip.

In some embodiments, the plurality of laser chip assemblies 200 are configured to emit laser beams of the same color, and the diffractive structures 312 of the diffractive optical element 3 are designed according to the wavelengths of the laser beams emitted from the laser chip assemblies 200.

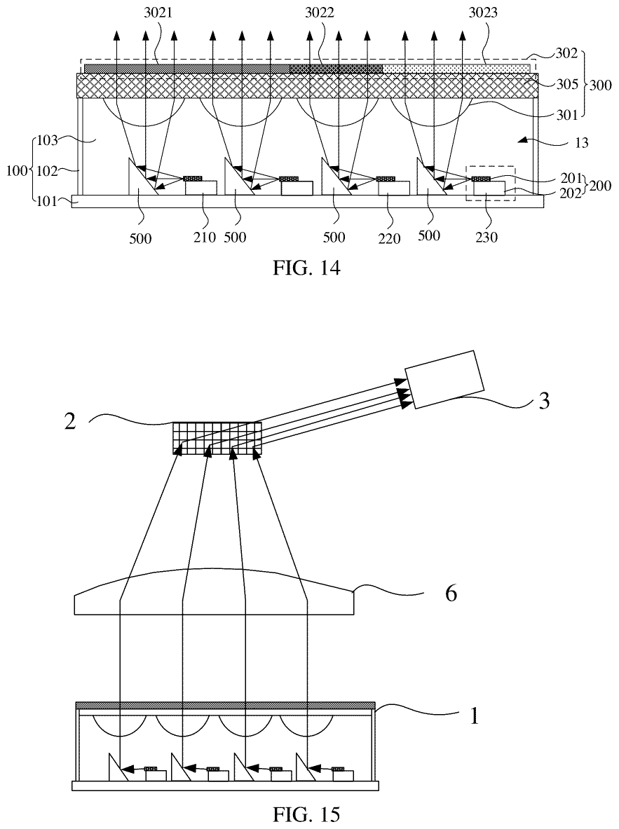

FIG. 14 is a sectional view of another laser device according to some embodiments.

In some embodiments, as shown in FIG. 14, the plurality of laser chip assemblies 200 include a plurality of red light laser chip assemblies 210, a plurality of green light laser chip assemblies 220, and a plurality of blue light laser chip assemblies 230.

The plurality of red light laser chip assemblies 210 are arranged in an array to constitute a red light laser chip assembly array, the plurality of green light laser chip assemblies 220 are arranged in an array to constitute a green light laser chip assembly array, and the plurality of blue light laser chip assemblies 230 are arranged in an array to constitute a blue light laser chip assembly array.

For example, the plurality of red light laser chip assemblies 210 include eight red light laser chip assemblies 210, and the eight red light laser chip assemblies 210 constitute a 2×4 red light laser chip assembly array.

For example, the plurality of green light laser chip assemblies 220 include four green light laser chip assemblies 220, and the four green light laser chip assemblies 220 constitute a 1×4 green light laser chip assembly array.

For example, the plurality of blue light laser chip assemblies 230 include four blue light laser chip assemblies 230, and the four blue light laser chip assemblies 230 constitute a 1×4 blue light laser chip assembly array.

In this way, the plurality of laser chip assemblies 200 constitute two rows of red light laser chip assemblies 210, one row of green light laser chip assemblies 220, and one row of blue light laser chip assemblies 230 that are arranged in sequence, that is, the plurality of laser chip assemblies 200 constitute a 4×4 laser chip assembly array.

Accordingly, the diffracting portion 302 includes a first diffracting portion 3021, a second diffracting portion 3022, and a third diffracting portion 3023. For example, the first diffracting portion 3021 is disposed on the light-output side of the red light laser chip assembly array, the second diffracting portion 3022 is disposed on the light-output side of the green light laser chip assembly array, and the third diffracting portion 3023 is disposed on the light-output side of the blue light laser chip assembly array.

The first diffracting portion 3021 is configured to shape and homogenize the laser beams emitted from the red light laser chip assemblies, the second diffracting portion 3022 is configured to shape and homogenize the laser beams emitted from the green light laser chip assemblies, and the third diffracting portion 3023 is configured to shape and homogenize the laser beams emitted from the blue light laser chip assemblies.

It should be noted that the red laser beams emitted from the red light laser chip assemblies 210, the green laser beams emitted from the green light laser chip assemblies 220, and the blue laser beams emitted from the blue light laser chip assemblies 230 may have different sizes and divergence angles. In this case, the parameters of the first diffracting portion 3021, the parameters of the second diffracting portion 3022, and the parameters of the third diffracting portion 3023 may be adjusted accordingly according to the optical path of light combination, the optical path of illumination, and the etendue required by the projection system 10, so as to be applicable for the actual application requirements.

In some embodiments, the plurality of laser chip assemblies 200 may also be arranged in other forms, and it is only necessary to adjust the parameters of the diffractive optical element according to the need of the laser device 1 for the emergent flat-topped beams such that the diffractive optical elements correspond to the laser chip assemblies 200.

It should be noted that, in some embodiments of the present disclosure, the arrangement structure of the laser chip assemblies 200 and the parameters of the diffractive optical elements are not limited.

Some embodiments of the present disclosure further provide a projection system 10. FIG. 15 is a structural diagram of a projection system according to some embodiments.

In some embodiments, as shown in FIG. 15, the projection system 10 includes a laser device 1 in any one of the above embodiments, a light modulation component 2 disposed on the light-output side of the laser device 1, and a projection lens 3 disposed on the light-output side of the light modulation component 2. The light beams emitted from the laser device 1 are flat-topped beams with a uniform intensity distribution.

After the laser beams are homogenized and shaped by the reshaping component 300 in the laser device 1, the laser beams emitted from the plurality of laser chip assembly arrays in the laser device 1 are combined into a rectangular light spot with a uniform light intensity distribution. After the rectangular light spot is incident on the light modulation component 2, the shape and size of the rectangular light spot match the shape and size of the light modulation component 2, and the light modulation component 2 can directly modulate the rectangular light spot emitted from the laser device 1 and transmit the modulated light beam to the projection lens 3. The, the projection lens 3 outputs the light beam and generates an image to project the image on a projection screen or at a set position.

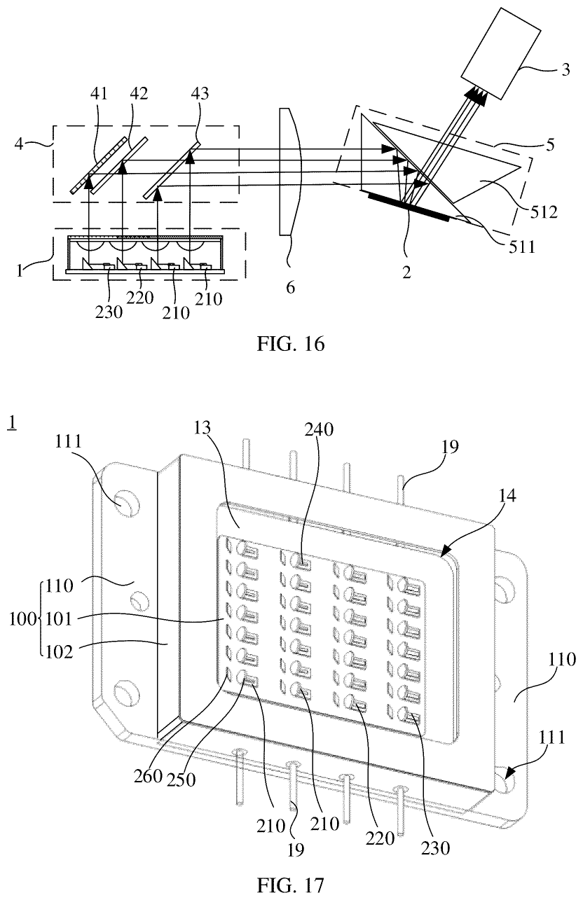

FIG. 16 is a structural diagram of another projection system according to some embodiments.

In some embodiments, as shown in FIG. 16, the projection system 10 further includes a light combining component 4, and the light combining component 4 is disposed between the laser device 1 and the light modulation component 2.

The laser beams emitted from the plurality of laser chip assemblies 200 in the laser device 1 form a plurality of independent irradiating light spots, and the light combining component 4 is configured to combine the plurality of independent irradiating light spots and reflect the combined light beam at a predetermined angle to the light modulation component 2. The light modulation component 2 modulates the combined light beam and transmits the modulated light beam to the projection lens 3. The projection lens 3 images the modulated light beam to project the image on a projection screen or at a set position.

In some embodiments, the projection system 10 includes a plurality of laser devices 1, and the light combining component 4 is further configured to combine the laser beams emitted from the different laser devices 1, which is not limited in the present disclosure.

In some embodiments, as shown in FIG. 16, the projection system 10 includes a laser device 1, and the light combining component 4 is configured to combine the laser beams emitted from the various laser chip assemblies 200 in that laser device 1.

For example, the laser device 1 includes a red light laser chip assembly 210, a green light laser chip assembly 220, and a blue light laser chip assembly 230, and the light combining component 4 includes a second reflecting mirror 41, a first light combining mirror 42, and a second light combining mirror 43.

The second reflecting mirror 41 is disposed in the light-output path of the blue light laser chip assembly 230, and is configured to reflect the blue laser beam emitted from the blue light laser chip assembly 230 to the first combining mirror 42. The first combining mirror 42 is disposed at the intersection of the light-output path of the second reflecting mirror 41 and the light-output path of the green light laser chip assembly 220, and is configured to transmit the blue laser beam and reflect the green laser beam emitted from the green light laser chip assembly 220. The second light combining mirror 43 is disposed at the intersection of the light-output path of the first light combining mirror 42 and the light-output path of the red laser chip assembly 210, and is configured to transmit the blue laser beam and the green laser beam and reflect the red laser beam emitted from the red laser chip assembly 210. In this way, the red laser beam, the green laser beam, and the blue laser beam are combined to form a composite beam, and the composite beam is emitted from one side of the second light combining mirror 43 to the light modulation component 2.

It should be noted that in the case that the projection system 10 includes a plurality of laser devices 1, the light combining components 4 may be set with reference to the above light combining principle, which is not repeated in this disclosure.

In some embodiments, as shown in FIG. 16, the projection system 10 includes a reflection component 5. The reflection component 5 is arranged on the light-output side of the light combining component 4, and is configured to change the propagation path of the light beam (e.g., the composite beam), so as to shorten the length of the projection system 10, thereby facilitating the miniaturized design of the projection system 10. The reflection component 5 includes at least one total reflection prism 51.

For example, the at least one total reflection prism 51 includes a first total reflection prism 511 and a second total reflection prism 512 arranged opposite to each other. When the composite beam is incident at a predetermined angle on the transmissive and reflective surface of the first total reflection prism 511, the incident angle of the composite beam satisfies the total reflection condition of the transmissive and reflective surface of the first total reflection prism 511. In this case, the transmissive and reflective surface of the first total reflection prism 511 can totally reflect the composite beam to the light modulation component 2. Then, the light beam, which has been modulated by the light modulation component 2, is reflected by the light modulation component 2 to the transmissive and reflective surface. At this time, the modulated light beam does not satisfy the total reflection condition of the transmissive and reflective surface, and thus can be emitted from the transmissive and reflective surface to the second total reflection prism 512. The second total reflection prism 512 refracts the modulated light beam such that the modulated light beam can be vertically incident on the projection lens 3.

In some embodiments, the reflection component 5 includes a third reflecting mirror. After the composite beam is incident on the third reflecting mirror at a predetermined angle, the third reflecting mirror can reflect the composite beam to the light modulation component 2 in a direction that satisfies the incident angle of the light modulation component 2, and the light modulation component 2 modulates and outwardly emits the composite beam to the projection lens 3.

In some embodiments, the light modulation component 2 includes a DMD, which is a reflective optical device. The DMD includes a plurality of fourth reflecting mirrors, and each of the fourth reflecting mirrors is individually driven to deflect. By controlling the deflection angles of the reflecting fourth mirrors, the light beams can be modulated and reflected to the projection lens 3.

In some embodiments, the light modulation component 2 further includes a liquid crystal display (LCD), liquid crystal on silicon (LCOS) light valve, or the like, which is not limited herein.

In some embodiments, as shown in FIG. 15 and FIG. 16, the projection system 10 further includes an illumination lens group 6 disposed between the laser device 1 and the light modulation component 2. The illumination lens group 6 is configured to shape and homogenize the composite beam such that the composite beam meets the usage requirements of the light modulation component 3.

It is to be understood that the projection system 10 is applicable for a wider range of use scenarios by providing the illumination lens group 6 in the projection system 10 to further shape and homogenize the composite beam at incidence onto the light modulation component 2.

In some embodiments, the illumination lens group 6 is disposed between the laser device 1 and the light modulation component 2, as shown in FIG. 15. In some embodiments, the illumination lens group 6 is disposed between the light combining component 4 and the reflection component 5, as shown in FIG. 16. In some embodiments, the projection system 10 includes more or fewer optical elements to achieve the reshaping functions or other functions for light beams, and in this case the illumination lens group 6 may be set according to actual needs. The illumination lens group 6 includes one or more lenses as long as it can achieve the reshaping functions for light.

It is to be understood that the laser device 1 in the projection system 10 is configured to emit laser beams of a plurality of colors, and the display effect of the projection picture formed by the laser beams depends on the symmetry, overlapping degree, light combination uniformity and the like of the laser beams. Therefore, in the field of laser projection, in order to achieve imaging quality with higher brightness and higher color gamut coverage, three kinds of monochrome laser chips are used as a full-color laser projection light source in the laser device 1. However, when the laser device 1 emits laser beams of three primary colors through the three kinds of laser chips, the laser light source of the three primary colors suffers from speckles.

For this reason, some embodiments of the present disclosure provide another projection system 10. The projection system 10 includes a reflective diffraction grating, and the reflective diffraction grating can tune the laser beams of specific wavelengths emitted from the plurality of laser chip assemblies, such that different laser chip assemblies can operate at different center wavelengths. Thus, the coherence between the plurality of laser beams can be reduced by changing the wavelengths of the laser beams emitted from the laser chip assemblies, thereby inhibiting the generation of speckles.

In some embodiments, the projection system 10 is a holographic projection system. The projection system 10 includes a laser device 1 (i.e., a laser light source package structure), a projection lens, and a light modulation component. The laser device 1 is configured to provide laser beams of three primary colors. The light modulation component is configured to modulate laser beams emitted from the laser device 1 and transmit the modulated laser beams to the projection lens for output and imaging by the projection lens, and the projection lens projects the image on a projection screen or at a set position. The projection lens includes a plurality of mirrors for focusing regulating the imaging effect.

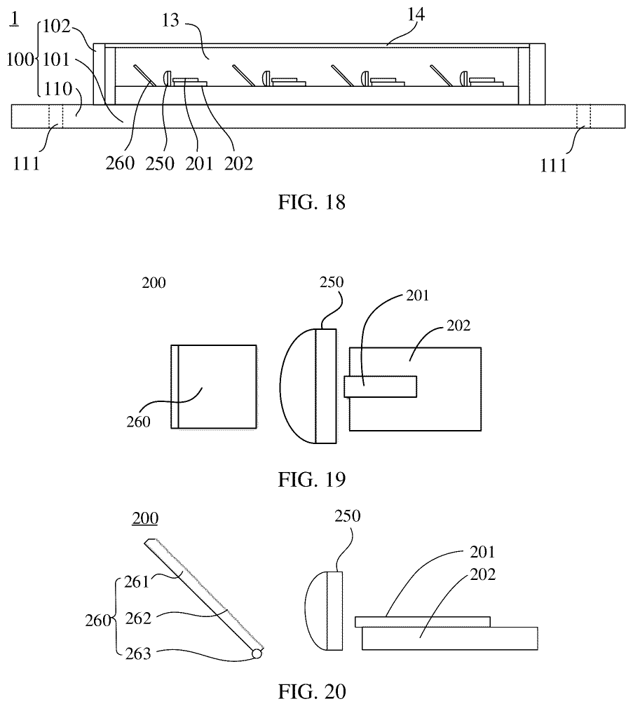

FIG. 17 is a three-dimensional diagram of another laser device according to some embodiments, and FIG. 18 is a sectional view of another laser device according to some embodiments.

In some embodiments, as shown in FIG. 17 and FIG. 18, the laser device 1 includes a housing 100 and a plurality of laser chip assemblies 200.

The housing 100 includes a bottom plate 101 and a sidewall 102. The sidewall 102 is arranged around the bottom plate 101 and defines an accommodation cavity 13 together with the bottom plate 101. The plurality of laser chip assemblies 200 are arranged in the accommodation cavity 13. The side of the sidewall 102 away from the bottom plate 101 is open to form a light outlet, and a plurality of laser beams emitted from the plurality of laser chip assemblies 200 can be emitted from the light outlet to the outside of the laser device 1.

In some embodiments, the housing 100 is a metal material piece. For example, the housing 100 is a copper material piece. It is to be understood that copper has a large thermal conductivity coefficient, and can conduct the heat generated when the laser chip assemblies 200 emit light to the outside of the housing 100, thereby reducing the temperature inside the accommodation cavity 13, which is beneficial for improving the light emitting performance of the laser chip assemblies 200 and prolonging the service life of the laser chip assemblies 200.

In some embodiments, the projection system 10 further includes a holder for securing the laser device 1. As shown in FIG. 17, the housing 100 further includes two connecting plates 110. The two connecting plates 110 are arranged on two sides of the bottom plate 101 and are fixedly connected to the holder.

For example, the laser device 1 is further provided with a plurality of connecting holes 111. Some of the plurality of connecting holes 111 are provided in one connecting plate 110, and the other connecting holes 111 are provided in the other connecting plate 110. A plurality of through holes are provided in the holder of the projection system 10 at positions corresponding to the plurality of connecting holes 111, and fasteners are threaded through the connecting holes 111 and the corresponding through holes to fix the laser device 1 to the holder, which can also increase the stability of the housing 100.

In some embodiments, the connecting holes 111 are bolt holes, riveted through holes, or the like. In this case, the fasteners are bolts, screws, rivets, or the like.

In some embodiments, the laser device 1 further includes a snap-fit structure, and the laser device 1 is snap-fit to the holder of the projection system 10 by the snap-fit structure, which is not limited in the present disclosure.

The bottom plate 101 is arranged at the bottom of the sidewall 102, and the bottom plate 101 is arranged to face the light outlet of the housing 100. The bottom plate 101 is configured to carry the plurality of laser chip assemblies 200.

The plurality of laser chip assemblies 200 are arranged in an array on the bottom plate 101. For example, the plurality of laser chip assemblies 200 are arranged in a plurality of rows and columns on the bottom plate 101. The plurality of laser chip assemblies 200 include a plurality of red light laser chip assemblies 210, a plurality of green light laser chip assemblies 220, and a plurality of blue light laser chip assemblies 230.

The red light laser chip assemblies 210, the green light laser chip assemblies 220, and the blue light laser chip assemblies 230 emit red laser light, green laser light, and blue laser light, respectively, to form a full-color laser projection light source for the projection system 10.

It should be noted that the embodiments in the present disclosure are all illustrated schematically with an example where the laser chip assemblies 200 emit blue laser light, green laser light, and red laser light at the same time. In some embodiments, the laser chip assemblies 200 may also only emit any two colors of laser light among the blue laser light, the green laser light, and the red laser light, which is not limited in the present disclosure.

In some embodiments, the laser chip assemblies 200 emitting laser light of the same color are arranged in one column, and all of the laser chip assemblies 200 in each column of laser chip assemblies 200 are connected in series.

For example, all of the laser chip assemblies 200 in each column of laser chip assemblies 200 are connected in series with each other by gold wires. That is, the plurality of laser chip assemblies 200 are arranged in red light laser chip assembly columns, green light laser chip assembly columns, and blue light laser chip assembly columns. The red light laser chip assembly columns, the green light laser chip assembly columns, and the blue light laser chip assembly columns are arranged alternately, thereby ensuring that the laser beams emitted from the plurality of laser chip assemblies 200 are uniformly mixed.

In some embodiments, as shown in FIG. 17 and FIG. 18, the plurality of laser chip assemblies 200 are arranged in four laser chip assembly columns. The four laser chip assembly columns include two red light laser chip assembly columns, one green light laser chip assembly column, and one blue light laser chip assembly column.

In some embodiments, the plurality of laser chip assemblies 200 are arranged in five, six, or more laser chip assembly columns, and the plurality of laser chip assembly columns include at least one red light laser chip assembly column, at least one green light laser chip assembly column, and at least one blue light laser chip assembly column.

In some embodiments, as shown in FIG. 17, the laser device 1 further includes a plurality of electrode pins 19. The plurality of electrode pins 19 are arranged in pairs on two sides of the housing 100. Each pair of electrode pins 19 corresponds to one laser chip assembly column, and each pair of electrode pins 19 includes a positive pin and a negative pin. Each pair of electrode pins 19 is electrically connected to one laser chip assembly column so as to electrically connect the laser chip assembly column to an external power supply. The external power supply is configured to supply power to the plurality of laser chip assemblies 200 such that the plurality of laser chip assemblies 200 emit laser beams.

For example, if four laser chip assembly columns correspond to four pairs of electrode pins 19, the laser chip assemblies 200 are electrically connected to the external power supply via the four pairs of electrode pins 19.

FIG. 19 is a top view of a laser chip assembly of another laser device according to some embodiments.

In some embodiments, as shown in FIG. 18 and FIG. 19, the laser chip assembly 200 includes a laser chip 201, a heat sink 202, a collimating lens 250, and a reflective diffraction grating 260. The laser chip 201 is configured to emit laser beams.

The laser chip 201 is arranged on the heat sink 202. A front cavity surface of the laser chip 201 is coated with an antireflection film, such that the reflectivity of the front cavity surface of the laser chip 201 is less than 1%. The laser chip 201 is soldered to the heat sink 202 by a eutectic process.

The heat sink 202 is arranged on the bottom plate 101 and is configured to conduct heat generated when the laser chip 201 emits light to the bottom plate 101, and the heat is conducted from the bottom plate 101 to the sidewall 102 and then is emitted to the outside from sidewall 102. For example, the heat sink 202 is made of aluminum nitride AlN, silicon carbide SiC, and the like.

In some embodiments, the red light laser chip assembly 210 includes a red light laser chip, the blue light laser chip assembly 230 includes a blue light laser chip, and the green light laser chip assembly 220 includes a green light laser chip. In this way, different laser chips emit laser beams of different colors (e.g., laser beams of three primary colors), and a full-color laser projection light source can be provided for the light modulation component 2.

The collimating lens 250 is arranged between the laser chip 201 and the reflective diffraction grating 260, and is disposed on the light-output side of the laser chip 201. The collimating lens 250 is configured to collimate laser beams, and emit the collimated laser beams to the reflective diffraction grating 260. The laser beams, after being collimated by the collimating lens 250, have a high reflectivity when they are incident on the reflective diffraction grating 260.

In some embodiments, an antireflection film is provided on the surface of the collimating lens 250 to enhance the collimating effect of the collimating lens 250. The antireflection film is configured to anti-reflect full-spectrum beams or beams of a predetermined wavelength band.

In some embodiments, the collimating lens 250 is a convex lens, a plano-convex lens, a Fresnel lens, or the like, as long as it can achieve the effect of collimating laser beams, which is not limited in the present disclosure.

In some embodiments, the collimating lens 250 is a plano-convex lens, that is, the collimating lens 250 includes a convex arc surface and a planar surface, and the convex arc surface and the planar surface are arranged opposite to each other. The plane surface faces the light-output side of the laser chip 201, and the convex arc surface faces the reflective diffraction grating 260. The collimating lens 250 is an integral piece or a split piece, which is not limited in the present disclosure. For example, the shape of the convex arc surface is spherical or aspherical.

The reflective diffraction grating 260 is arranged on the light-output side of the collimating lens 250. The reflective diffraction grating 260 is configured to reflect the laser beams collimated by the collimating lens 250 and adjust the center wavelengths of the laser beams, such that the laser light emitted from the various laser chips 201, after being reflected by the reflective diffraction grating 260, has different center wavelengths, which can alleviate the speckling phenomenon in the projection system 10 and is beneficial for the simplification of the optical path of the laser device 1 and is beneficial for the miniaturized design of the projection system 10 and the laser device 1.

FIG. 20 is a front view of a laser chip assembly of another laser device according to some embodiments.

In some embodiments, as shown in FIG. 20, the reflective diffraction grating 260 includes a first reflecting mirror 261, a grating portion 262, and a dispensing portion 263. The grating portion 262 is arranged on the surface of the side of the first reflecting mirror 261 facing the collimating lens 250, and is configured to change the phase of the laser beam at incidence onto the grating portion 262. In some embodiments, the grating portion 262 is further configured to change the center wavelength of the laser beam at incidence onto the grating portion 262.

The dispensing portion 263 is arranged on the side of the first reflecting mirror 261 close to the bottom plate 101. Adhesive is coated in the dispensing portion 263, which can fixedly connect the first reflecting mirror 261 and the bottom plate 101. For example, the dispensing portion 263 is a dispensing groove, etc., which is not limited in the present disclosure.

In some embodiments, the first reflecting mirror 261 is also fixed to the bottom plate 101, for example, by soldering.

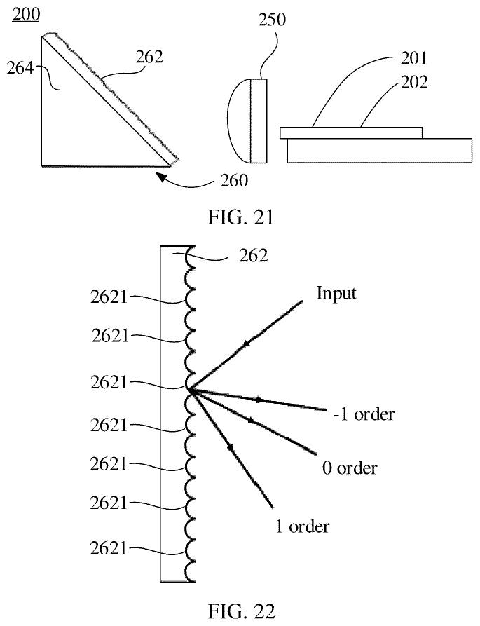

FIG. 21 is a side view of another laser chip assembly of another laser device according to some embodiments.

In some embodiments, as shown in FIG. 21, the reflective diffraction grating 260 includes a right-angled reflection prism 264 and a grating portion 262.

The bottom surface of the right-angled reflection prism 264 is fixedly connected to the bottom plate 101. For example, the bottom surface of the right-angled reflection prism 264 is fixedly connected to the bottom plate 101 by means of adhesion, snap-fitting, or the like. The grating portion 262 is formed on a beveled surface (i.e., a side surface of the reflection prism 264 facing the collimating lens 250) of the right-angled reflection prism 264. For example, the grating portion 262 is directly formed on the beveled surface of the right-angled reflection prism 264 by laser device micromachining or photoetching.

FIG. 22 is a schematic diagram showing diffraction orders of a reflective diffraction grating according to some embodiments.

In some embodiments, as shown in FIG. 22, the grating portion 262 of the reflective diffraction grating 260 includes a plurality of sub-grating portions 2621. The plurality of sub-grating portions 2621 are periodically arranged at equal spacing and have parallel scribed lines, which can change the phases of laser beams. For example, the plurality of sub-grating portions 2621 include a plurality of orders of sub-grating portions 2621, e.g., a zeroth-order sub-grating portion, a first-order sub-grating portion, and the like. Different orders of sub-grating portions 2621 are configured to receive laser beams of different wavelengths, and laser beams diffract in different orders on different orders of sub-grating portions 2621. In addition, in the laser beams of different wavelengths emitted from the laser chips 201, the laser beams of corresponding wavelengths that are incident on different orders of sub-grating portions 2621 have different optical powers.

For example, the zeroth-order sub-grating portion is configured to receive a laser beam of a first wavelength, and the laser beam of the first wavelength is subjected to zeroth-order diffraction on the zeroth-order sub-grating portion. For example, the optical power of the laser beam of the first wavelength occupies 20% to 50% of the optical power of the laser beams emitted from the laser chip 201.

For example, the first-order sub-grating portion is configured to receive a laser beam of a second wavelength, and the laser beam of the second wavelength is subjected to first-order diffraction on the first-order sub-grating portion. For example, the optical power of the laser beam of the second wavelength occupies 50% to 80% of the optical power of the laser beams emitted from the laser chip 201.

It is to be understood that, in order to achieve the diffraction effect, the laser beams which occupy the majority of the optical power in the laser beams of different wavelengths emitted from the laser chip 201 need to be laser beams of the second wavelength, so as to diffract in the first order at the first-order sub-grating portion.

When the laser beam passes through the grating portion 262, the structure of the sub-grating portion 2621, the incident angle of the laser beam, and the diffraction angle of the reflective diffraction grating 260 satisfy formula (2), that is:

$$d ( sin {θ}_{α} + sin {θ}_{i} ) = n λ ; \qquad formula ( 2 )$$

In formula (2), d represents the period of the sub-grating portion 2621, θ_{α} represents the incident angle of the laser beam, θᵢ represents the diffraction angle of the reflective diffraction grating 260, n represents the diffraction order of the sub-grating portion 2621, where n=±1, ±2, ±3, and the like, and λ represents the wavelength of the laser beam after passing through the sub-grating portion 2621.

It is to be understood that according to formula (2), when the incident angle of the laser beam at incidence onto the reflective diffraction grating 260 is equal to the diffraction angle of the reflective diffraction grating 260, the laser beam is subjected to the first-order diffraction having the maximum efficiency on the first-order sub-grating portion, i.e., θ_{α}=θᵢ.

According to formula (2), the grating formula is:

$$2 d sin {θ}_{littrow} = λ ; \qquad formula ( 3 )$$

In formula (3), O_{littrow} represents a Littrow angle.

The incident angle of the laser beam collimated by the collimating lens 250 relative to the reflective diffraction grating 260 is a constant value, that is, the incident angle θ_{α} relative to the reflective diffraction grating 260 is a constant value. Thus, when the diffraction order of the reflective diffraction grating 260 is 1 (i.e., n=1), the Littrow angle θ_{littrow} is equal to the blaze angle of the reflective diffraction grating 260. The blaze angle is an angle between the grating reflective surface and the surface of the sub-grating portion 2621, and the grating reflective surface is the working surface of the reflective diffraction grating 260, that is, the blaze angle is also an angle between the normal of the reflective surface and the normal of the grating plane.

Thus, the tuning wavelength A of the reflective diffraction grating 260 is only related to the period d of the sub-grating portion 2621. Accordingly, in order to change the wavelength A, the period d of each sub-grating portion 2621 can be changed.

In some embodiments, a plurality of sub-grating portions 2621 are formed by depositing a metal film on the optical element and etching the metal film to form a plurality of parallel grooves, thereby forming the reflective diffraction grating 260. For example, a material such as diamond, a prism, or glass is deposited on the optical element. For example, a metal film is etched by laser device micromachining or photoetching to form a plurality of sub-grating portions 2621, such that a plurality of sub-grating portions 2621 with a smaller spacing are obtained.

In some embodiments, the reflective diffraction grating 260 is a metal grating. The metal grating is provided with a metal reflective surface. The metal reflective surface has a high reflectivity, and is configured to reflect laser beams. For example, the reflective diffraction grating 260 is made of a metal material such as gold, silver, aluminum, and the like.

According to formula (3), the period d of the sub-grating portion 2621 of the reflective diffraction grating 260 matches the wavelength of the laser beam emitted from the laser chip 201. Therefore, in some embodiments, the red light laser chip assembly 210 further includes a first color portion that matches the red light laser chip, and the period of the first reflection grating portion matches the wavelength of red laser light. The green light laser chip assembly 220 further includes a second reflection grating portion that matches the green light laser chip, and the period of the second reflection grating portion matches the wavelength of green laser light. The blue light laser chip assembly 230 includes a third reflection grating portion that matches the blue light laser chip, and the period of the third reflection grating portion matches the wavelength of blue laser light.

In some embodiments, the laser device 1 further includes a cover plate 14, and the cover plate 14 is arranged on the housing 100 and blocks off the light outlet of the housing 100 to seal the accommodation cavity 13. The cover plate 14 is made of a transparent material. For example, the cover plate 14 is made sealing glass, sapphire, quartz, or the like.

In some embodiments, a semi-reflective film is arranged on the side surface of the cover plate 14 facing the accommodation cavity 13, and an antireflection film is provided on the side surface of the cover plate 14 away from the accommodation cavity 13. Understandably, the laser beams diffracted by the reflective diffraction grating 260 pass through the cover plate 14 and are emitted out of the light outlet. With the arrangements above, the laser beams return back along the original path and form an external resonant cavity with the rear cavity surface of the laser chip 201, and the laser beams finally emitted from the cover plate 14 have different center wavelengths from each other.

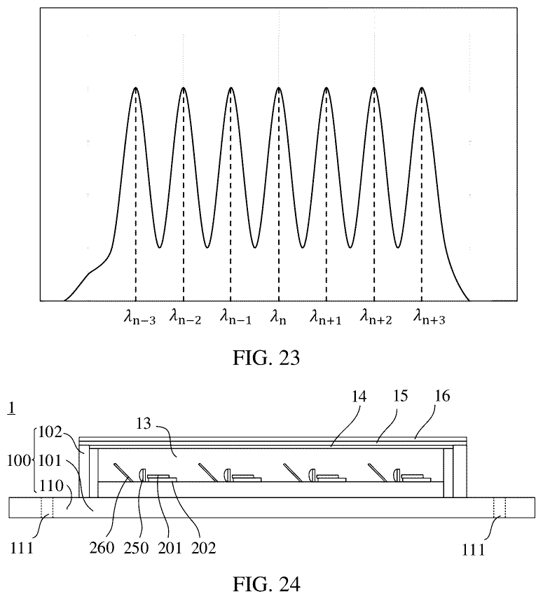

FIG. 23 is graph showing a wavelength distribution of a laser chip assembly of another laser device after wavelength tuning according to some embodiments. As shown in FIG. 23, the above laser device 1 can achieve the purpose of tuning the wavelength and inhibiting speckles.

In some embodiments, the reflectivity of the cover plate 14 is less than 5%, that is, the cover plate 14 does not affect the output power of the laser device 1 and can achieve the oscillation of the external resonant cavity. Laser beams that are partially reflected at the cover plate 14 form a resonant cavity with the laser chip 201, and wavelength tuning is achieved by laser device oscillation of the resonant cavity.

FIG. 24 is a sectional view of another laser device according to some embodiments.

In some embodiments, as shown in FIG. 24, the laser device 1 further includes a homogenizing member 15. The homogenizing member 15 is arranged on the side of the cover plate 14 away from the accommodation cavity 13 and is configured to uniformly distribute the laser beams emitted out of the cover plate 14. For example, the homogenizing member 15 is a fly-eye lens, a light pipe or the like. The fly-eye lens can homogenize laser beams. Moreover, the area of the light incoming surface of the light pipe is smaller than the area of the emergent end. After laser beams having a larger beam angle enter the light pipe and are reflected by the light pipe, the emergent light has a smaller beam angle, thereby homogenizing and collimating the laser beams and dissipating the speckles.

In some embodiments, as shown in FIG. 24, the laser device 1 further includes a diffusion sheet 16. The diffusion sheet 16 is arranged on the side of the cover plate 14 away from the accommodation cavity 13, and is configured to diffuse and homogenize the laser beams emitted out of the cover plate 14, so as to uniformly diffuse the three-color laser beams and dissipate the speckles.

It will be appreciated by those skilled in the art that the scope of the present disclosure is not limited to the specific embodiments described above, and that certain elements of the embodiments may be modified and replaced without departing from the spirit of the present disclosure. The scope of the present disclosure is limited by the appended claims.

What is claimed is:

1. A laser device, comprising:
a housing, comprising:
a bottom plate; and
a sidewall connected to the bottom plate;
a plurality of laser chip assemblies arranged on the bottom plate; and
a reshaping component connected to the sidewall, wherein the reshaping component defines a first enclosed space together with the housing, and the plurality of laser chip assemblies is disposed within the first enclosed space, and the reshaping component is disposed in a light-output path of at least a portion of the laser chip assemblies.

2. The laser device according to claim 1, wherein the reshaping component comprises:
a plurality of first collimating portions arranged in correspondence to the plurality of laser chip assemblies, wherein each of the plurality of first collimating portions is configured to receive and collimate a laser beam emitted from a corresponding laser chip assembly; and
a diffracting portion comprising a plurality of diffraction structures, wherein the plurality of diffraction structures are distributed in two dimensions;
wherein a laser beam emitted from one of the laser chip assemblies is collimated by a corresponding first collimating portion and then is homogenized by the diffracting portion.

3. The laser device according to claim 2, wherein the diffractive structures comprise at least one of a serrated structure, a trapezoidal structure, a tilted rectangular structure or a stepped structure.

4. The laser device according to claim 2, further comprising a plurality of reflecting mirrors disposed within the housing; wherein any one of the plurality of reflecting mirrors corresponds to at least one laser chip assembly of the plurality of laser chip assemblies and is disposed on a light-output side of the corresponding at least one laser chip assembly; the reflecting mirror is configured to receive at least one laser beam emitted from the corresponding at least one laser chip assembly and reflect the at least one laser beam to at least one first collimating portion of the plurality of first collimating portions.

5. The laser device according to claim 4, wherein the reshaping component further comprises a substrate, the substrate defining the first enclosed space together with the housing; wherein the plurality of first collimating portions are arranged on a first side of the substrate facing the laser chip assemblies, and the diffracting portion is arranged on second side of the substrate facing away from the laser chip assemblies.

6. The laser device according to claim 5, wherein the first collimating portion is one of a convex lens or a Fresnel lens, and protrudes towards the laser chip assemblies.

7. The laser device according to claim 4, wherein the reshaping component further comprises:
a first substrate defining the first enclosed space together with the housing; and
a second substrate disposed within the first enclosed space;
wherein the reshaping component satisfies one of the following:
the first substrate is attached to the second substrate; the plurality of first collimating portions are disposed on a first side of the first substrate facing the laser chip assemblies, and the diffracting portion is disposed on a second side of the second substrate facing away from the laser chip assemblies; or
the first substrate and the second substrate are spaced apart from each other by a set distance in a direction perpendicular to the bottom plate; the plurality of first collimating portions are disposed on a side of the first substrate facing the laser chip assemblies; and the reshaping component comprises at least one diffracting portion disposed on at least one side of the second substrate.

8. The laser device according to claim 7, wherein the first collimating portion is one of a convex lens or a Fresnel lens, and protrudes towards one side of the laser chip assembly.

9. The laser device according to claim 2, further comprising:
a plurality of curved reflecting mirrors, disposed within the housing and corresponding to the plurality of laser chip assemblies; wherein each of the plurality of curved reflecting mirrors is disposed on a light-output side of a corresponding laser chip assembly; a surface of a side of the curved reflecting mirror facing the corresponding laser chip assembly is constructed as a concave curved surface; the curved reflecting mirror is configured to receive a laser beam emitted from the corresponding laser chip assembly, collimate the received laser beam, and reflect the collimated laser beam to the diffracting portion;
the reshaping component further comprises a substrate defining the first enclosed space together with the housing;
wherein the diffracting portion satisfies one of the following:
the diffracting portion is disposed on a first side of the substrate facing away from the curved reflecting mirror; or
the diffracting portion is disposed on a second side of the substrate facing the curved reflecting mirror.

10. The laser device according to claim 9, wherein the reshaping component further comprises a plurality of second collimating portions; wherein the plurality of second collimating portions are disposed in correspondence to the plurality of laser chip assemblies, and the second collimating portion is configured to receive and collimate a laser beam emitted from a corresponding laser chip assembly;
wherein the reshaping component satisfies one of the following:
the diffracting portion is disposed on a first side of the substrate facing away from the curved reflecting mirror, and the plurality of second collimating portions are disposed on a second side of the substrate facing the curved reflecting mirror; or
the diffracting portion is disposed on a first side of the substrate facing the curved reflecting mirror, and the plurality of second collimating portions are disposed on a second side of the substrate facing away from the curved reflecting mirror.

11. The laser device according to claim 2, wherein the plurality of laser chip assemblies are arranged in correspondence to the plurality of diffractive structures, and a diffractive structure corresponding to each of the laser chip assemblies is constructed to match a wavelength of laser light emitted from the laser chip assembly.

12. The laser device according to claim 1, further comprising:
a support portion arranged on an inner wall of the sidewall and extending circumferentially along the sidewall; and
sealing glass connected to the support portion and blocking off the support portion; wherein the bottom plate, a portion of the sidewall, the support portion, and the sealing glass together define a second enclosed space;
wherein the sealing glass is fixed to the support portion by soldering, and the reshaping component is fixed to the housing by adhesive glue.

13. The laser device according to claim 1, wherein the laser chip assembly comprises:
a laser chip configured to emit a laser beam; and
a reflective diffraction grating arranged on a light-output side of the laser chip; wherein a period of the reflective diffraction grating matches a wavelength of the laser beam emitted from the laser chip; and the reflective diffraction grating is configured to reflect the laser beam and adjust a center wavelength of the laser beam;
wherein a plurality of laser beams emitted from a plurality of laser chips in the plurality of laser chip assemblies, after being reflected by a plurality of reflective diffraction gratings in the plurality of laser chip assemblies, have different center wavelengths.

14. The laser device according to claim 13, wherein an incident angle of the laser beam at incidence onto the reflective diffraction grating is equal to a diffraction angle of the reflective diffraction grating.

15. The laser device according to claim 13, wherein the reflective diffraction grating is a metal grating, the metal grating comprising a metal reflective surface configured to reflect the laser beam.

16. The laser device according to claim 13, wherein the reflective diffraction grating comprises:
a first reflecting mirror arranged at an angle on the bottom plate; and
a grating portion arranged on a side of the first reflecting mirror facing the laser chip, wherein the grating portion is configured to change at least one of a phase or a center wavelength of the laser beam at incidence onto the grating portion.

17. The laser device according to claim 13, wherein the reflective diffraction grating comprises:
a right-angled reflection prism, wherein a bottom surface of the right-angled reflection prism is fixedly connected to the bottom plate; and
a grating portion arranged on a side of the right-angled reflection prism facing the laser chip, wherein the grating portion is configured to change at least one of a phase or a center wavelength of the laser beam at incidence onto the grating portion.

18. The laser device according to claim 13, wherein the laser chip assembly further comprises a collimating lens, wherein the collimating lens is arranged between the laser chip and the reflective diffraction grating, and is configured to collimate the laser beam and transmit the collimated laser beam onto the reflective diffraction grating.

19. The laser device according to claim 13, wherein the plurality of laser chip assemblies comprise:
at least one red light laser chip assembly arranged in at least one column, the red light laser chip assembly comprising:
a red light laser chip configured to emit red laser light; and
a first reflection grating, wherein a grating period of the first reflection grating matches a wavelength of the red laser light emitted from the red light laser chip;
at least one green light laser chip assembly arranged in at least one column, the green light laser chip assembly comprising:
a green light laser chip configured to emit green laser light; and
a second reflection grating, wherein a grating period of the second reflection grating matches a wavelength of the green laser light emitted from the green laser chip; and
at least one blue light laser chip assembly arranged in at least one column, the blue light laser chip assembly comprising:
a blue light laser chip configured to emit blue laser light; and
a third reflection grating, wherein a grating period of the third reflection grating matches a wavelength of the blue laser light emitted from the blue light laser chip.

20. A laser projection system, comprising: at least one laser device according to claim 1, a light modulation component disposed on a light-output side of the laser device, and a projection lens disposed on a light-output side of the light modulation component.
